(19) United States
(12) Patent Application Publication
(10) Pub. No.: US 2024/0363548 A1
(43) Pub. Date: Oct. 31, 2024

(54) WAFER HAVING TRENCHES

(71) Applicant: SK hynix Inc., Gyeonggi-do (KR)

(72) Inventors: Geon Hee KIM, Gyeonggi-do (KR); Hyung Jin PARK, Gyeonggi-do (KR); Seung Won LEE, Gyeonggi-do (KR)

(21) Appl. No.: 18/461,503

(22) Filed: Sep. 6, 2023

(30) Foreign Application Priority Data
Apr. 28, 2023 (KR) 10-2023-0056142

(51) Int. Cl. H01L 23/00; H01L 21/66; H01L 23/522; H01L 23/528

(52) U.S. Cl. CPC H01L 23/562; H01L 22/34; H01L 23/5226; H01L 23/5283

(57) ABSTRACT

A wafer includes chip areas and a first scribe lane disposed between the chip areas, and a first trench pattern disposed in the first scribe lane. The first scribe lane extends in a first direction. The first trench pattern includes a plurality of first trench groups spaced apart from each other in the first direction.

The present application claims priority under 35 U.S.C. § 119 to Korean Patent Application No. 10-2023-0056142, filed on Apr. 28, 2023 in the Korean Intellectual Property Office, which is incorporated herein by reference in its entirety.

### BACKGROUND

### 1. Field

The present invention disclosure relates generally to semiconductor technology and more particularly to semiconductor manufacturing technology. The present invention disclosure provides an improved wafer having a plurality of trenches and a method of manufacturing a semiconductor device.

### 2. Description of the Related Art

An improved technology for manufacturing a plurality of semiconductor chips by dividing wafers is proposed.

### SUMMARY

The present invention disclosure provides an improved wafer having a plurality of trenches and a method of manufacturing a semiconductor device.

According to an embodiment of the present invention disclosure a wafer is provided which includes a plurality of chip areas, a first scribe lane disposed between the chip areas, and a first trench pattern disposed in the first scribe lane. The first scribe lane extends in a first direction. The first trench pattern includes a plurality of first trench groups spaced apart from each other in the first direction.

According to another embodiment of the present invention disclosure a wafer is provided which includes a substrate including chip areas and a scribe lane between the chip areas. The scribe lane includes dummy metal patterns over the substrate, dummy top metal patterns over the dummy metal patterns, a redistribution insulating layer over the dummy top metal patterns, and a plurality of trenches vertically passing through the redistribution insulating layer. The plurality of trenches may vertically overlap with the dummy metal patterns and the dummy top metal patterns.

Yet another embodiment of the present disclosure provides a method of manufacturing a semiconductor device. The method includes preparing a substrate having chip areas and scribe lanes, forming dummy metal patterns in the scribe lane over the substrate, forming an interlayer insulating layer surrounding the dummy metal patterns, forming dummy top metal patterns over the dummy metal patterns and the interlayer insulating layer, forming a passivation layer covering the dummy top metal patterns, forming a redistribution insulating layer over the passivation layer, forming trenches vertically passing through the redistribution insulating layer, and performing a singulation process along the trenches.

These and other features and advantages of the present invention will become apparent to the skilled person from the following drawings and detailed description of embodiments of the invention.

### BRIEF DESCRIPTION OF THE DRAWINGS

FIG. 1 is a top view schematically showing a wafer according to an embodiment of the present invention.

FIGS. 2A to 2C are enlarged views of a region A of FIG. 1, and

FIGS. 3A to 3E are enlarged views of a region B of FIG. 1.

FIGS. 4A and 4B are longitudinal cross-sectional views taken along the line I-I′ of FIG. 1 to schematically illustrate wafers for manufacturing semiconductor devices according to embodiments of the present disclosure.

FIG. 5 is an enlarged view illustrating the trenches T1 to T4 according to embodiments of the present disclosure.

FIG. 6 is an enlarged view illustrating shapes of trenches Ta-Td having various sidewall inclination angles according to embodiments of the present invention.

FIGS. 7A to 7E are views illustrating a method of manufacturing a semiconductor device by forming trenches and performing a singulation process according to an embodiment of this disclosure.

### DETAILED DESCRIPTION

Example embodiments of the present invention will be described below in more detail with reference to the accompanying drawings. The present invention may, however, be embodied in different forms and should not be construed as limited to the embodiments set forth herein.

Rather, these embodiments are provided so that this disclosure convey the scope of the present invention to those skilled in the art. Throughout the disclosure, like reference numerals refer to like parts throughout the various figures and embodiments of the present invention.

It will be understood that, although the terms “first” and/or “second” may be used herein to describe various elements, these elements should not be limited by these terms. These terms are only used to distinguish one element from another element. For instance, a first element discussed below could be termed a second element without departing from the teachings of the present disclosure. Similarly, the second element could also be termed the first element.

Other expressions that explain the relationship between elements, such as “between”, “directly between”, “adjacent to” or “directly adjacent to” should be construed in the same way.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

An embodiment of the present disclosure provides a physically stable singulation process in a semiconductor chip manufacturing process.

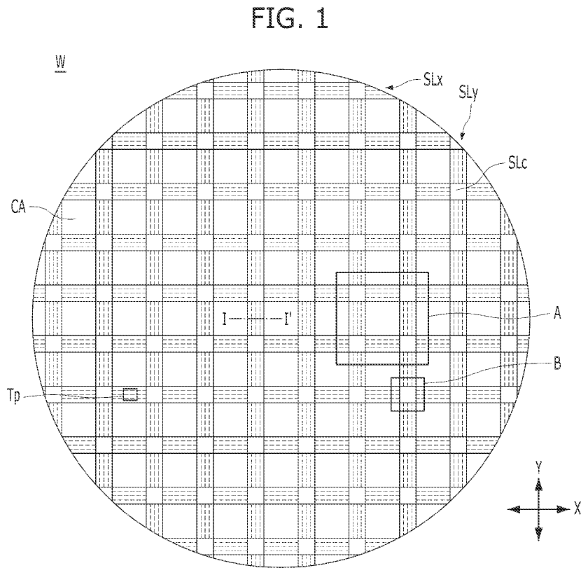

FIG. 1 is a top view schematically showing a wafer W according to an embodiment of the present invention. Referring to FIG. 1 a wafer (i.e., a substrate) W according to an embodiment of the disclosure may include chip areas (i.e., first regions) CA and scribe lanes (i.e., second regions) SL. The chip areas CA may be arranged in a matrix form. The scribe lanes SL may be disposed in a lattice shape between the chip areas CA. The scribe lanes SL may include row scribe lanes SLx extending in a row direction X, column scribe lanes SLy extending in a column direction Y, and cross-intersection areas SLc in which the row scribe lanes SLx and the column scribe lanes SLy intersect. Trench patterns Tp may be disposed in the scribe lanes SL. The row direction X and the column direction Y may be perpendicular to each other.

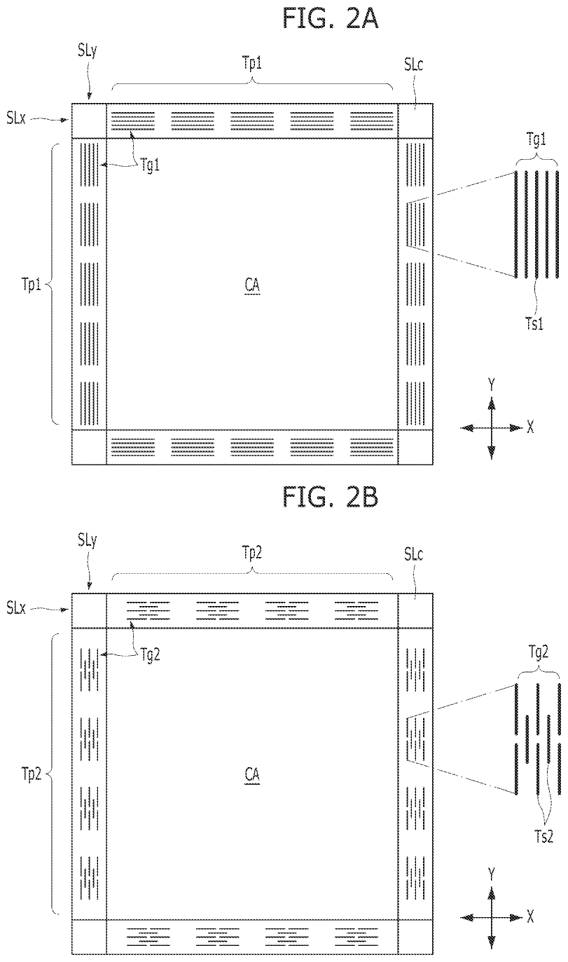

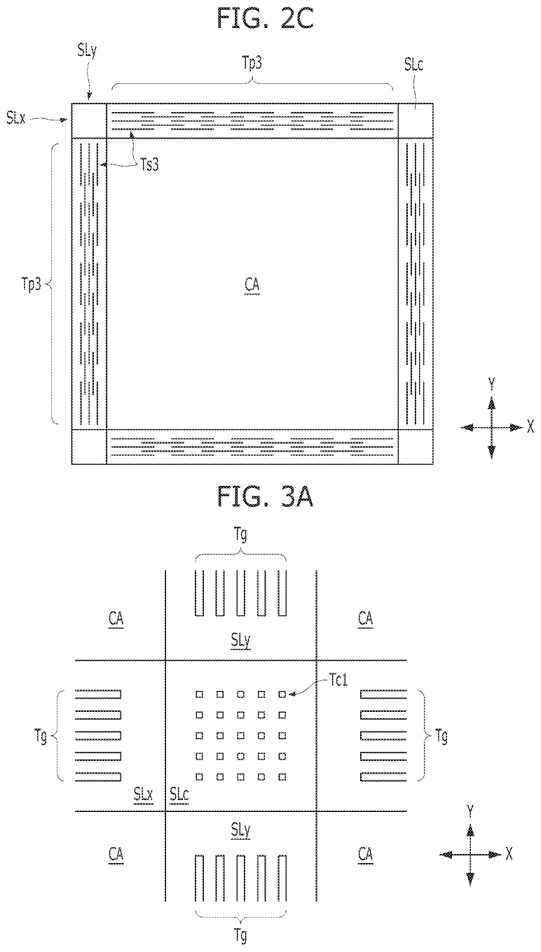

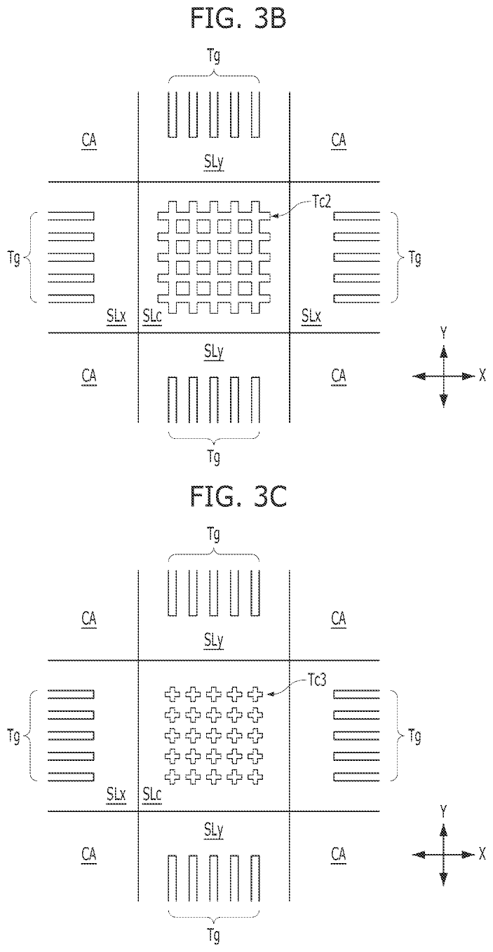

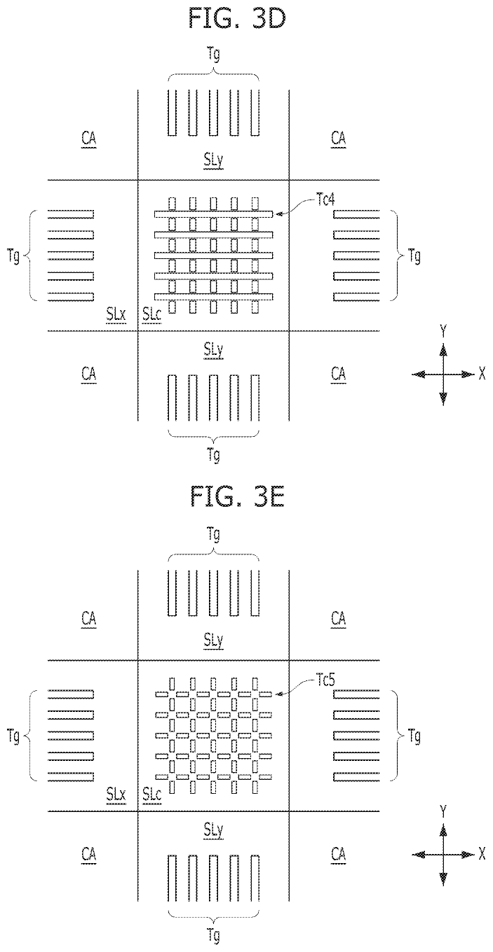

FIGS. 2A to 2C are enlarged views of a region A of FIG. 1, and FIGS. 3A to 3E are enlarged views of a region B of FIG. 1. Referring to FIG. 2A, trench patterns Tp1 according to an embodiment of the present disclosure may include a plurality of trench groups Tg1. The plurality of trench groups Tg1 may be disposed to be spaced apart from each other in the row direction X and the column direction Y, respectively in a periphery of the chip area CA. Each of the trench groups Tg1 may include a plurality of trenches Ts1 spaced apart from each other. Each of the plurality of trenches Ts1 may have a line segment shape in a top view. The plurality of trenches Ts1 in each trench group Tg1 may extend in parallel with each other. For example, some of the plurality of the trench groups Tg1 that are disposed in the row scribe lanes SLx may include the plurality of trenches Ts1 extending and being spaced apart from each other in the row direction X, and others of the plurality of the trench groups Tg1 that are disposed in the column scribe lanes SLy may include the plurality of trenches Ts1 extending and being spaced apart from each other in the column direction Y. In the drawings, it is illustrated as an example that each of the trench groups Tg1 includes five trenches Ts1, but the inventive concept of the disclosure is not limited in this way. For example, in some embodiments, each trench group Tg1 may include at least one trench Ts1. Also, as an example, in other embodiments, each trench group Tg1 may include more than 5 trenches Ts1.

Referring to FIG. 2B, trench patterns Tp2 according to an embodiment of the present disclosure may include a plurality of trench groups Tg2. The plurality of trench groups Tg2 may be disposed to be spaced apart from each other in the row direction X and the column direction Y, respectively. Each of the trench groups Tg2 may include a plurality of trenches Ts2 that are disposed to be staggered or off-set. For example, the trenches Ts2 may extend in the row direction X and may be arrayed to be staggered or off-set in the column direction Y, or the trenches Ts2 may extend in the column direction Y and be arrayed to be staggered or off-set in the row direction X.

Referring to FIG. 2C, trench patterns Tp3 according to an embodiment of the present disclosure may include a plurality of trenches Ts3 arranged to be staggered or off-set. Each of the trenches Ts3 may extend in the row direction X or the column direction Y, and may be spaced apart from each other in the row direction X and the column direction Y.

Referring to FIGS. 1 and 3A to 3E, a wafer (i.e., a substrate) according to an embodiment of the present disclosure may include various cross-intersection trench patterns Tc1 to Tc5 disposed in the cross-intersection area SLc. In an embodiment, referring to FIG. 1, the trench patterns Tp1 to Tp3 might not be formed in the cross-intersection areas SLc. Referring to FIGS. 3A to 3E, cross-intersection trench patterns Tc1 to Tc5 may be disposed in the cross-intersection areas SLc.

Referring to FIG. 3A, the cross-intersection trench pattern Tc1 may include a plurality of polygonal shaped trenches. For example, each of the polygonal shaped trenches of the cross-intersection trench patterns Tc1 may have a rectangular shape. In some embodiments, each of the polygonal shaped trenches of the cross-intersection trench patterns Tc1 may have a circular or dot shape.

Referring to FIG. 3B, the cross-intersection trench pattern Tc2 may have a plurality of line-shaped row trenches extending in parallel with each other in the row direction X and a plurality of line-shaped column trenches extending in parallel with each other in the column direction Y. For example, the cross-intersection trench pattern Tc2 may have a lattice shape.

Referring to FIG. 3C, the cross-intersection trench patterns Tc3 may have a plurality of cross patterns. For example, each of the cross patterns of the cross-intersection trench patterns Tc3 may have a segment-shaped row trench and a segment-shaped column trench intersecting each other in a cross shape.

Referring to FIG. 3D, the cross-intersection trench pattern Tc4 may include a plurality of line-shaped trenches spaced apart along the column direction and extending in parallel to each other in the row direction X. The cross-intersection trench pattern Tc4 also includes a plurality of segment-shaped trenches. Each segment-shaped trench comprises multiple short segments of the same disposed between line-shaped trenches to form a lattice shape. The individual segment-shaped trenches are extending in the column direction Y. In the illustrated embodiment of FIG. 3D six segment-shaped trenches are aligned in the column direction Y to form a column of the cross-intersection trench pattern Tc4, however, the inventive concept is not limited in this configuration only. The cross-intersection trench pattern Tc4 of FIG. 3D has five columns and five rows. In the embodiment of FIG. 3D, each of the plurality of segment-shaped trenches may be elongated in the column direction Y, and each of the plurality of line-shaped trenches may extend in the row direction X. In a variation of the illustrated embodiment of FIG. 3D, each of the plurality of segment-shaped trenches may be elongated in the row direction X, and each of the plurality of line-shaped trenches may extend in the column direction Y.

Referring to FIG. 3E, the cross-intersection trench pattern Tc5 may include segment-shaped trenches elongated in the row direction X and the column direction Y. The individual segment-shaped trenches might not intersect to each other. In FIG. 3E each row of the cross-intersection trench pattern Tc5 is made of six individual segment-shaped trenches aligned along the row direction X, while each column of the cross-intersection trench pattern Tc5 is made of six individual segment-shaped trenches aligned along the column direction Y, however the inventive concept is not limited to this.

The cross-intersection trench patterns Tc1 to Tc5 illustrated in FIGS. 3A to 3E according to the embodiments of the preset disclosure may be variously combined.

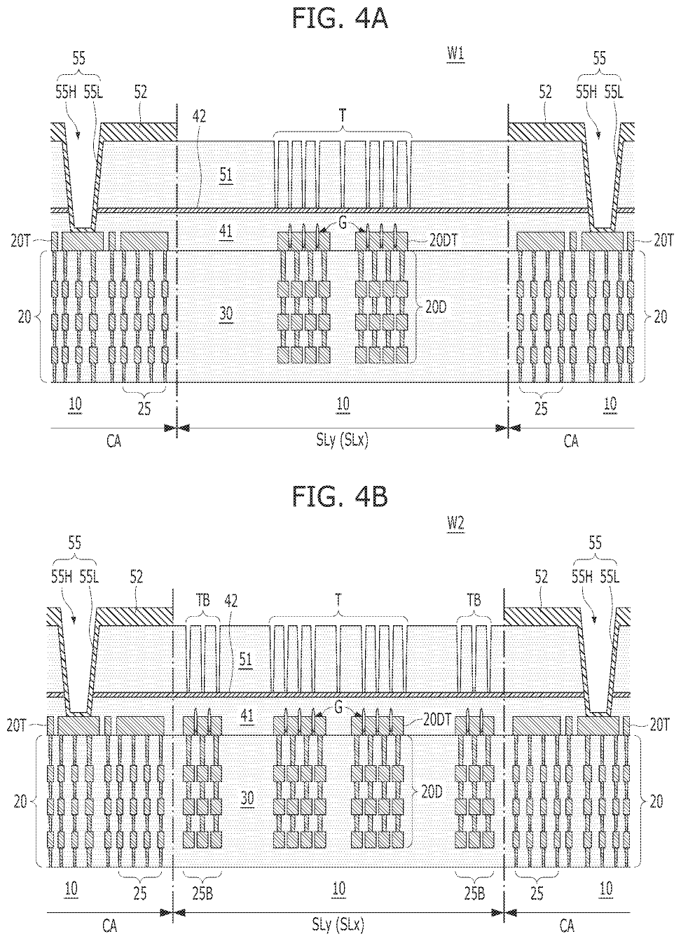

FIGS. 4A and 4B are longitudinal cross-sectional views taken along the line I-I′ of FIG. 1 to schematically illustrate wafers W1 and W2 for manufacturing semiconductor devices according to embodiments of the present disclosure. Referring to FIGS. 4A and 4B, the wafers W1 and W2 for manufacturing semiconductor devices may include chip areas CA and scribe lanes SLx and SLy between the chip areas CA. For example, the wafers W1 and W2 for manufacturing semiconductor devices may include first areas CA and second areas SLx and SLy between the first areas CA.

The chip areas CA may include metal patterns 20 and top metal patterns 20T, an interlayer insulating layer 30, passivation layers 41 and 42, a redistribution insulating layer 51, a redistribution interconnection layer 52, and a redistribution via structure 55.

The scribe lanes SLx and SLy may include dummy metal patterns 20D and dummy top metal patterns 20DT, the interlayer insulating layer 30, the passivation layers 41 and 42, the redistribution insulating layer 51, air gaps G, and trenches T disposed over or on a base layer 10. The base layer may include a silicon substrate or an insulating layer.

The metal patterns 20 in the chip areas CA may include multi-layered metal interconnections and metal vias. The metal patterns 20 may be conductive circuit elements for operating the semiconductor device.

The metal patterns 20 may further include a guard ring pattern 25. The guard ring pattern 25 may include a plurality of guard ring interconnections extending in a horizontal direction and a plurality of guard ring vias extending in a vertical direction. The guard ring pattern 25 may block cracks generated in the scribe lanes SLx and SLy from propagating to the chip areas CA.

The top metal patterns 20T may include an interconnection pattern or a pad pattern disposed on the metal patterns 20. The interlayer insulating layer 30 may surround the metal patterns 20. The interlayer insulating layer 30 be a single layer (as shown) or multilayer. The interlayer insulating layer 30 may include silicon oxide, silicon nitride or mixtures thereof. The interlayer insulating layer 30 may in an embodiment comprise multilayers of silicon oxide-based insulating layers and silicon nitride-based insulating layers alternating. In an embodiment the interlayer insulating layer 30 may comprise at least one pair of a silicon oxide, or silicon oxide-based insulating layer and a silicon nitride or silicon nitride-based insulating layer stacked on each other. A silicon oxide-based insulating layer as this term is used here means silicon oxy-nitride (SiON), silicon carbon oxide (SiCO), silicon hydrogen oxide (SiHO), silicon carbon hydrogen oxide (SiCHO), and dopants-doped silicon oxide, for example, BSG, PSG, BPSG, or etc. The dopant may include boron (B), phosphorous (P), arsenic (As), fluorine (F), antimony (Sb), or other materials including silicon and oxygen. A silicon nitride-based insulating layer as this term is used here means silicon carbon nitride (SiCN), silicon hydrogen nitride (SiHN), silicon carbon hydrogen nitride (SiCHN), silicon boron nitride (SiBN), silicon boron carbon nitride (SiBCN), or other materials including silicon and nitrogen.

The passivation layers 41 and 42 may include a lower passivation layer 41 and an upper passivation layer 42. The lower passivation layer 41 may surround and cover the top metal patterns 20T. The lower passivation layer 41 may include an oxide material having a low conformality so that it forms air gaps G when it is applied on the interlayer insulating layer 30. The air gaps G may be formed in the narrower spaces of the dummy top metal patterns 20DT because the low conformality material cannot enter these narrower spaces. For example, the lower passivation layer 41 may include high density plasma (HDP) oxide. The upper passivation layer 42 may be disposed on the lower passivation layer 41 to have an etching selectivity with respect to the lower passivation layer 41. The upper passivation layer 42 may include an insulating material harder and denser than the lower passivation layer 41. For example, the upper passivation layer 42 may include a silicon nitride-based insulating material. Because the upper passivation layer 42 is harder and denser than the lower passivation layer 41, cracks may be more likely to occur in the upper passivation layer 42 than the lower passivation layer 41. Accordingly, to prevent cracks occurring, the upper passivation layer 42 may be formed thinner than the lower passivation layer 41.

The redistribution insulating layer 51 may be disposed on the upper passivation layer 42. The redistribution insulating layer 51 may have a dielectric constant lower than that of the upper passivation layer 42. The redistribution insulating layer 51 may be formed sufficiently thick to reduce parasitic capacitance between the top metal patterns 20T and the redistribution interconnection layer 52. For example, the redistribution insulating layer 51 may be formed to be thicker than the lower passivation layer 41.

The redistribution interconnection layer 52 may include conductive metals such as aluminum (Al), tungsten (W), copper (Cu), nickel (Ni), gold (Au), and solder (SnAg). Specifically, the redistribution interconnection layer 52 may include aluminum (Al) that can satisfy excellent metal bonding, stable electrical properties, thermal conductivity, and flexibility. The redistribution interconnection layer 52 may be electrically connected to some of the top metal patterns 20T through the redistribution via structure 55.

The redistribution via structure 55 may include a redistribution via hole 55H and a redistribution via metal layer 55L. The redistribution via hole 55H may vertically and completely pass through the redistribution insulating layer 51 and the upper passivation layer 42, and partially pass through the lower passivation layer 41 to expose a top surface of the top metal pattern 20T. The redistribution via metal layer 55L may be conformally formed on inner walls of the redistribution via hole 55H and the exposed top surface of the top metal pattern 20T. The redistribution interconnection layer 52 and the redistribution via metal layer 55L may include the same metal and may be formed as one unified body or continuous layer.

The dummy metal patterns 20D and the dummy top metal patterns 20DT in the scribe lanes SLx and SLy may include multi-layered dummy metal interconnections and dummy metal vias. The dummy metal patterns 20D may include a process monitoring pattern or a test pattern.

The air gaps G may be formed and presented between the dummy top metal patterns 20DT. For example, the air gaps G may be defined by the lower passivation layer 41 to be formed and presented between the dummy top metal patterns 20DT. The air gaps G may provide a cutting path (sawing path or dicing path) in a sawing process, a dicing process, or a singulation process. The air gaps G may be formed through an insulating layer forming process having low conformity. For example, the air gaps G may be formed using a process of forming the lower passivation layer 41 including the HDP oxide.

The trenches T may be formed to vertically penetrate the redistribution insulating layer 51. The trenches T may be disposed to be vertically aligned and overlapped with the dummy metal patterns 20D and the dummy top metal patterns 20DT. The trenches T may be formed to have a horizontal width narrower than a horizontal width of the redistribution via holes 55H. The trenches T may be formed using a process of forming the redistribution via holes 55H. That is, the trenches T may be formed with the redistribution via holes 55H at the same time. Because the horizontal width of each of the trenches T is sufficiently narrower than the horizontal width of the redistribution via holes 55H, an etching rate of the redistribution insulating layer 51 in the scribe lanes SLx and SLy may be lower than an etching rate of the redistribution insulating layer 51 in the chip areas CA. Therefore, when the redistribution via hole 55H exposes the top surface of the top metal pattern 20T, bottom surfaces of the trenches T may expose inside the redistribution insulating layer 51 or the upper passivation layer 42. In an embodiment, the bottom surfaces of the trenches T may be located inside the lower passivation layer 41. In another embodiment, the bottom surfaces of the trenches T may expose a top surface of the dummy top metal pattern 20DT. In another embodiment, the bottom surfaces of the trenches T may be spatially connected to the air gaps G. According to the inventive concepts of the present disclosure, the trenches T may be formed using existing processes without additional photomasks and photolithography processes. That is, the trenches T according to the embodiment of the present disclosure may be formed by performing an existing process by modifying an existing photomask.

The trenches T may provide the cutting path (sawing path or dicing path) in the sawing process, the dicing process, or the singulation process. Accordingly, a stable singulation process with low crack generation or without crack propagation may be performed using low energy.

Referring to FIG. 4B, compared to the wafer W1 described in FIG. 4A, the wafer W2 may further include a barrier guard ring pattern 25B and barrier trenches TB disposed to be adjacent to the chip areas CA in the scribe lanes SLx and SLy.

The barrier guard ring pattern 25B and the barrier trenches TB may absorb cracks generated in central portions of the scribe lanes SLx and SLy. That is, the barrier guard ring pattern 25B and the barrier trenches TB may block cracks generated in the central portions of the scribe lanes SLx and SLy from propagating to the chip areas CA.

In another embodiment, the guard ring patterns 25B in the chip areas CA may be omitted. The sawing process or the dicing process may be performed in the central portions of the scribe lanes SLx and SLy. That is, the sawing process or dicing process can be performed in areas where the dummy metal patterns 20D, the dummy top metal patterns 20DT, and the trenches T are formed.

The barrier guard ring pattern 25B and the barrier trenches TB may be located to be adjacent to the chip areas CA, i.e., outer regions of the scribe lanes SLx and SLy, to block cracks generated from the central portions of the scribe lanes SLx and SLy.

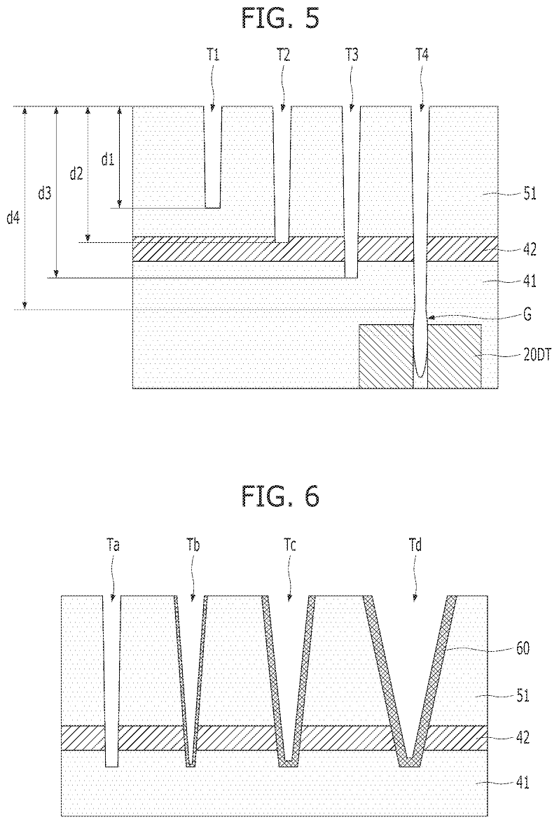

FIG. 5 is an enlarged view illustrating the trenches T1 to T4 according to embodiments of the present disclosure. Referring to FIG. 5, the trenches T1 to T4 may have various depths d1 to d4. The depths d1 to d4 of the respective trenches T1 to T4 may be determined according to singulation process energies. For example, the first trench T1 with a relatively shallow depth d1 may be formed when the singulation process energy is relatively high, and the third trench T3 with a relatively deep depth d3 may be formed when the singulation process energy is low. In a conventional process, the second trench T2 having a middle depth d2 may be formed. A bottom surface of the first trench T1 may be located inside the redistribution insulating layer 51. A bottom surface of the second trench T2 may expose the upper passivation layer 42. In an embodiment, the bottom surface of the second trench T2 may be located inside the upper passivation layer 42. A bottom surface of the third trench T3 may be located inside the lower passivation layer 41. In another embodiment, a fourth trench T4 may be formed to be spatially connected to the air gap G. According to the inventive concepts of the present disclosure, the singulation energies and the depths d1 to d4 of the trenches T1 to T4 may be variously selected and combined. According to the inventive concepts of the present disclosure, the singulation process may be stably performed using low energy in processes for manufacturing a semiconductor device.

FIG. 6 is an enlarged view illustrating shapes of trenches Ta to Td having various sidewall inclination angles according to embodiments of the present invention. Referring to FIG. 6, the trenches Ta to Td may have various sidewall inclination angles. As the sidewall inclination angle is smaller, the capping insulating layer 60 may be formed thicker on the inner sidewalls of each of the trenches Ta to Td. The capping insulating layer 60 may block moisture penetrating. Accordingly, the sidewall inclination angles of the trenches Tato Td may be adjusted and set so that the capping insulating layer 60 having an appropriate thickness may be formed. The capping insulating layer 60 may include at least one of silicon nitride-based inorganic insulating materials. The shapes of the trenches Ta to Td illustrated in FIG. 6 are exaggerated to facilitate understanding of the inventive concepts of the present disclosure.

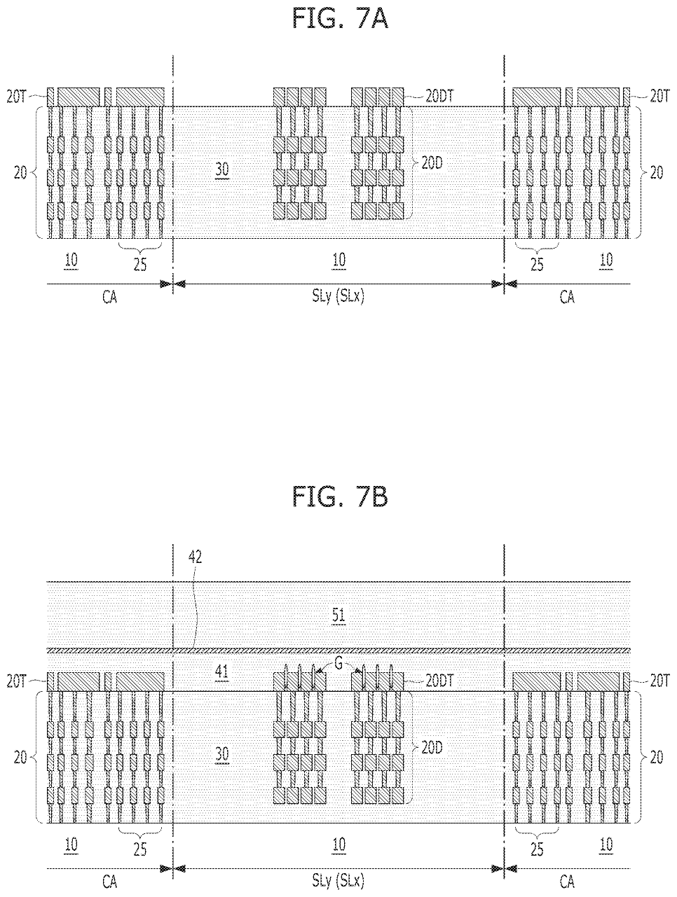

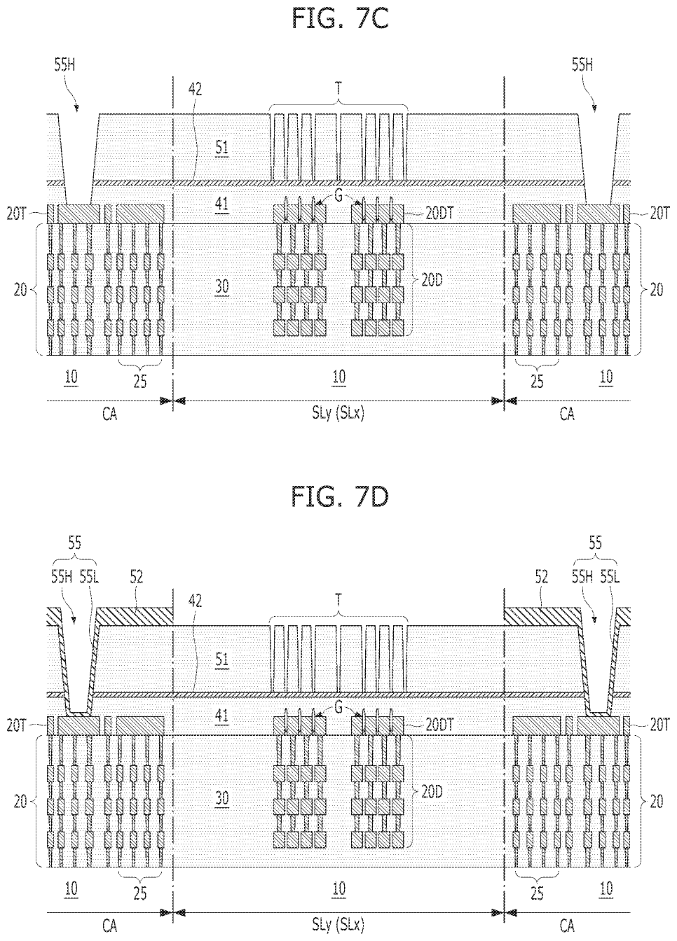

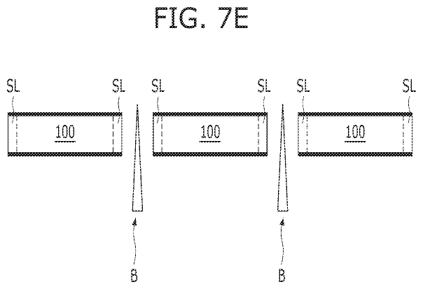

FIGS. 7A to 7E are views illustrating a method of manufacturing a semiconductor device 100 by forming trenches T and performing a singulation process according to an embodiment of this disclosure.

Referring to FIG. 7A, the method may include preparing a substrate 10 having chip areas CA and scribe lanes SLx and SLy. The substrate 10 may be in a wafer level.

The method may further include forming metal patterns 20 and dummy metal patterns 20D on the substrate 10 (i.e., the wafer). The metal patterns 20 may be formed in chip the areas CA, and the dummy metal patterns 20D may be formed in the scribe lanes SLx and SLy.

The method may further include forming an interlayer insulating layer 30 surrounding the metal patterns 20 in the chip area CA and the dummy metal patterns 20D in the scribe lanes SLx and SLy. The metal patterns 20, the dummy metal patterns 20D, and the interlayer insulating layer 30 may include multi-layered material layers, respectively. Accordingly, processes for forming the metal patterns 20, the dummy metal patterns 20D, and the interlayer insulating layer 30 may be repeatedly performed, respectively.

The method may further include forming top metal patterns 20T on the interlayer insulating layer 30 in the chip area CA and forming dummy top metal patterns 20DT on the interlayer insulating layer 30 in the scribe lanes SLx and SLy.

Referring to FIG. 7B, the method may further include forming a lower passivation layer 41 covering the top metal patterns 20T and the dummy top metal patterns 20DT, forming an upper passivation layer 42 on the lower passivation layer 41, and forming a redistribution insulating layer 51 on the upper passivation layer 42, each formed in the chip area CA and the scribe lanes SLx and SLy. The lower passivation layer 41 may be formed by performing an HDP (high density plasma) oxide deposition process. The lower passivation layer 41 may have a low conformality not to completely fill spaces between the dummy top metal patterns 20DT. Accordingly, the lower passivation layer 41 may define air gaps G between the dummy top metal patterns 20DT in the scribe lanes SLx and SLy. In an embodiment, the air gaps G may also be formed between the top metal patterns 20T in the chip areas CA.

Referring to FIG. 7C, the method may further include forming redistribution via holes 55H and trenches T. For example, the method may include forming the redistribution via holes 55H that vertically penetrate or pass through the redistribution insulating layer 51 in the chip areas CA to expose some top surfaces of the top metal patterns 20T, and forming the trenches T that vertically penetrate or pass through the redistribution insulating layer 51 in the scribe lanes SLx and SLy. Further referring to FIG. 5, the bottoms of the trenches T may be located inside the redistribution insulating layer 51, inside the upper passivation layer 42, or inside the lower passivation layer 41. In an embodiment, the bottoms of the trenches T may be spatially connected with the air gaps G. The redistribution via holes 55H and the trenches T may be formed by the same process at the same time.

Referring to FIG. 7D, the method may further include forming a redistribution via metal layer 55L on inner walls and a bottom of the redistribution via hole 55H and a redistribution interconnection layer 52 on the redistribution insulating layer 51 in the chip areas CA. The redistribution via metal layer 55L may be conformally formed on the inner walls of the redistribution via hole 55H and surfaces of the top metal patterns 20T exposed in the bottom of the redistribution via hole 55H. A redistribution via structure 55 including the redistribution via hole 55H and the redistribution via metal layer 55L may be formed. The redistribution interconnection layer 52 may also be formed in the scribe lanes SLx and SLy. In the scribe lanes SLx and SLy, the redistribution interconnection layer 52 may remain or be removed. In the drawing, the redistribution interconnection layer 52 is removed in the scribe lanes SLx and SLy.

In an embodiment, the method may further include forming a capping insulating layer (60 in FIG. 6) on an entire surface. The capping insulating layer 60 may include a silicon nitride-based insulating material.

Referring to FIG. 7E, the method may further include dividing and separating the semiconductor devices 100 along the scribe lanes SLx and SLy by performing a singulation process. A cutting blade B may divide and separate the semiconductor devices 100 along the scribe lane SL (SLx and SLy). The cutting blade B may be a sawing blade. In another embodiment, the cutting blade B may be replaced with a laser beam.

According to embodiments of the present disclosure, a wafer on which semiconductor chips are formed may include trenches formed in scribe lanes. A singulation process may be performed in a physically stable way by using trenches. In addition, the trenches can be formed using existing processes without additional photomasks or performing a photolithography processes.

While the present invention has been described with respect to the specific embodiments, it will be apparent to those skilled in the art that various changes and modifications may be made without departing from the scope of the invention.

What is claimed is:

1. A substrate comprising:
chip areas;
a first scribe lane disposed between the chip areas; and a first trench pattern disposed in the first scribe lane,
wherein the first scribe lane extends in a first direction, and the first trench pattern includes a plurality of first trench groups spaced apart from each other in the first direction.

2. The substrate of claim 1, wherein each of the first trench groups includes a plurality of first trenches extending in the first direction.

3. The substrate of claim 2, wherein the plurality of first trenches have segments shapes parallel with each other in a top view.

4. The substrate of claim 1, wherein:
the first trenches may be arranged off-set in a second direction, and
the first direction is perpendicular to the second direction.

5. The substrate of claim 1, further comprising:
a second scribe lane disposed between the chip areas; and
a second trench pattern disposed in the second scribe lane,
wherein:
the second scribe lane extends in the second direction,
the first direction is perpendicular to the second direction, and
the second trench pattern includes a plurality of second trenches extending in the second direction.

6. The substrate of claim 5, wherein:
the second trench pattern includes a plurality of second trench groups spaced apart from each other in the second direction, and
each of the plurality of second trench groups includes the plurality of second trenches.

7. The substrate of claim 5, further comprising:
a cross-intersection area where the first scribe lane and the second scribe lane cross each other; and
a cross-intersection trench pattern disposed in the cross-intersection area.

8. The substrate of claim 1, further comprising:
a barrier guard ring pattern disposed in the first scribe lane to be adjacent to the chip areas; and
a barrier trench disposed in the first scribe lane to be vertically aligned with the barrier guard ring pattern.

9. The substrate of claim 1, further comprising:
dummy metal patterns disposed in the first scribe lane to be vertically aligned with the first trench pattern;
an interlayer insulating layer surrounding the dummy metal patterns;
dummy top metal patterns disposed over the dummy metal patterns and the interlayer insulating layer; and
a passivation layer surrounding the dummy top metal patterns.

10. The substrate of claim 1, further comprising:
air gaps between the dummy top metal patterns, and
wherein the air gaps are defined by the passivation layer.

11. A wafer comprising:
a substrate including chip areas and a scribe lane between the chip areas,
wherein the scribe lane includes:
dummy metal patterns over the substrate;
dummy top metal patterns over the dummy metal patterns;
a redistribution insulating layer over the dummy top metal patterns; and
a plurality of trenches vertically passing through the redistribution insulating layer,
wherein the plurality of trenches vertically overlap with the dummy metal patterns and the dummy top metal patterns.

12. The wafer of claim 11, further comprising air gaps between the dummy top metal patterns.

13. The wafer of claim 12, further comprising:
an interlayer insulating layer surrounding the dummy metal patterns; and
a passivation layer surrounding the dummy top metal patterns,
wherein the passivation layer defines the air gaps.

14. The wafer of claim 11,
each of the chip areas includes:
metal patterns over the substrate;
top metal patterns over the metal patterns;
redistribution insulating layers over the top metal patterns:
a redistribution via hole vertically passing through the redistribution insulating layer and exposing a surface of a portion of the top metal patterns;
a redistribution via metal layer on an inner wall of the redistribution via hole and over the exposed surface of the top metal patterns; and
a redistribution layer disposed over the redistribution insulating layer.

15. The wafer of claim 11, further comprising:
a capping insulating layer formed on the inner walls of the trenches.
